(19) United States
(12) Patent Application Publication
(10) Pub. No.: US 2011/0290295 A1
(43) Pub. Date: Dec. 1, 2011

(54) Thermoelectric/solar cell hybrid coupled via vacuum insulated glazing unit, and method of making the same

(75) Inventor: Vijayen S. Veerasamy, Ann Arbor, MI (US)

(73) Assignee: Guardian Industries Corp., Auburn Hills, MI (US)

(21) Appl. No.: 12/801,257

(22) Filed: May 28, 2010

(51) Int. Cl. H01L 35/00; H01L 35/34

(52) U.S. Cl. 136/224; 438/55; 136/201; 257/E31.001

(57) ABSTRACT

Certain example embodiments provide techniques for improving the output of hybrid systems comprising photovoltaic (PV) and thermoelectric (TE) modules in conjunction with super-insulating, yet optically transmissive, vacuum insulated glass (VIG) unit technologies. More particularly, certain example embodiments relate to hybrid systems including hydrogenated microcrystalline silicon (mc-Si), hydrogenated amorphous silicon (a-Si), bulk hetero junction solar cell, and/or the like, that may be used together with a TE generator, that achieves high operational PV and TE efficiencies under ambient conditions. In that regard, certain example embodiments effectively partition the solar spectrum in order to yield an increased conversion efficiency of a PV-TE hybrid system with a solar cell operating at ambient temperature.

### FIELD OF THE INVENTION

Certain example embodiments of this invention relate to hybrid systems comprising thermoelectric (TE) and photovoltaic (PV) modules provided in connection with a vacuum insulated glass (VIG) unit, and/or methods of making the same. More particularly, certain example embodiments of this invention relate to systems comprising TE modules connected in series and thermally connected in parallel in the cavity of a VIG unit, with strip solar cells being provided on a substrate located on the non-light incident side of the VIG unit, and methods of making the same. Advantageously, certain example embodiments are able to partition the solar spectrum in order to increase the efficiency of a PV-TE hybrid system such that light in the infrared spectrum is used primarily for the operation of the TE modules, whereas light in the visible spectrum is used primarily for the operation of the solar cells.

### BACKGROUND AND SUMMARY OF EXAMPLE EMBODIMENTS OF THE INVENTION

Thermoelectric cells rely on the thermoelectric effect, which generally refers to the conversion of temperature differences to electric voltage and vice versa. In such systems, at the atomic scale, an applied temperature gradient causes charged carriers (e.g., electrons or electron holes) in the material to diffuse from the hot side to the cold side. Thus, a thermoelectric device creates a voltage when there is a different temperature on each side. This effect thus can be used to generate electricity.

Unfortunately, thermoelectric cells have had limited applications. Part of the problem is that such cells are expensive to make in efficient forms and typically require a significant energy source to provide the necessary heat, in the first place. One of the most successful applications for thermoelectric cells has been in satellites, which use thermocouples to produce energy so that they can be self-sustaining. In such applications, heat is generated either by the satellite's internal power source or absorbed on its sun facing side, and the “cold” is readily supplied by the vacuum of dark space. The hot and cold creates a powerful thermocouple process that can harvest usable energy from the IR portion of the solar spectrum. Such conditions are not easily replicable on Earth, however.

At the other extreme, photovoltaic devices also are known (e.g., see U.S. Pat. Nos. 6,784,361, 6,288,325, 6,613,603, and 6,123,824, the disclosures of which are hereby incorporated herein by reference). Some of photovoltaic devices incorporate inorganic-based solar cells. A problem with these solar cells relates to the substantial decrease in operational efficiency as the junction temperature increases. Typical silicon-based solar cells do not operate well at high temperatures, as their efficiency drops by at least 10% due to higher dark current. Also, for Si based solar cells, for example, about 25% of solar radiation is not useful at all, inasmuch as Si based solar cells function based on their exposure to portions of the visible spectrum as opposed to IR radiation.

Some recent efforts have attempted to divert the part of radiation not used by the solar cells in into thermoelectric modules to generate electricity. However, for the above-discussed and/or reasons, TE generators at or near sea-level cannot sustain a high delta T between the hot and cold junctions and, hence, systems based on this concept have not been able to operate at their full potential.

Thus, it will be appreciated that there is a need in the art for thermoelectric modules that operate at an increased efficiency on Earth and/or methods of making the same. It also will be appreciated that there is a need in the art for improved hybrid photovoltaic/thermoelectric systems and/or methods of making the same.

One aspect of certain example embodiments relates to hybrid systems comprising photovoltaic (PV) and thermoelectric (TE) modules in conjunction with super-insulating, yet optically transmissive, vacuum insulated glass (VIG) units.

Another aspect of certain example embodiments involves enabling TE modules to absorb a portion of the infrared radiation impinging thereon while allowing solar cells to absorb a portion of the visible light impinging thereon.

Another aspect of certain example embodiments relates to providing high temperature differentials for the hot and cold sides of the TE modules, while also thermally insulating the PV modules.

Still aspect of certain example embodiments relates to providing TE modules within the VIG unit itself.

Still another aspect of certain example embodiments relates to providing the TE modules electrically in serial and thermally in parallel.

Yet another aspect of certain example embodiments relates to focusing visible light on PV modules using cylindrical lenses.

Yet another aspect of certain example embodiments relates to using the pillars of the VIG unit as waveguides to help concentrate visible light on solar cells.

In certain example embodiments of this invention, an assembly is provided. First and second substantially parallel, spaced-apart substrates at least partially define a cavity therebetween, with the cavity being evacuated to a pressure less than atmospheric. A plurality of pillars is provided between the first and second substrates. An edge seal is provided around the periphery of the first and/or second substrate(s). At least one bus bar is provided in the cavity and supported by the second substrate. A plurality of thermoelectric modules is located in the cavity and on the at least one bus bar such that said thermoelectric modules are thermally in parallel, with each said thermoelectric module including a n-leg and a p-leg. A third substrate supports at least one solar cell, with the third substrate being substantially parallel to the second substrate and being located on a side of the second substrate opposite the first substrate. At least one thermocouple is formed such that the cavity corresponds to a hot side of the at least one thermocouple and an area outside the cavity proximate to the third substrate corresponds to a cold side of the at least one thermocouple. Adjacent thermoelectric modules are connected to one another via junctions such that the thermoelectric modules are electrically in series.

In certain example embodiments of this invention, a method of making a hybrid thermoelectric/photovoltaic system is provided. A first substrate is provided. At least one bus bar is formed on the first substrate. A plurality of thermoelectric modules is formed on the first substrate at least partially over the at least one bus bar, with each said thermoelectric module including an n-leg and a p-leg. Junctions are formed between adjacent thermoelectric modules so as to electrically connect the thermoelectric modules in series. A plurality of pillars is formed on the first substrate. A second substrate is provided in substantially parallel, spaced-apart relation to the first substrate so as to at least partially define a cavity therebetween. An edge seal is provided around the periphery of the first and/or second substrate(s). The cavity is evacuated to a pressure less than atmospheric. A backing substrate is provided. At least one solar cell is disposed on the backing substrate. The backing substrate is connected to the first substrate such that the second substrate and the backing substrate are provided in substantially parallel, spaced-apart relation to one another, with the side of the backing substrate having the at least one solar cell disposed thereon facing a side of the first substrate that does not have the plurality of thermoelectric modules formed thereon. At least one thermocouple is formed such that the cavity corresponds to a hot side of the at least one thermocouple and an area outside the cavity proximate to the backing substrate corresponds to a cold side of the at least one thermocouple. The plurality of thermoelectric modules is thermally in parallel in the cavity.

In certain example embodiments of this invention, a hybrid thermoelectric/photovoltaic system is provided. A vacuum insulating glass (VIG) unit includes a cavity evacuated to a pressure less than atmospheric. At least one bus bar is provided in the cavity. A plurality of thermoelectric modules is located in the cavity and on the at least one bus bar such that said thermoelectric modules are thermally in parallel, with the thermoelectric modules including junctions between adjacent n- and p-legs of the thermoelectric modules such that the thermoelectric modules are electrically in series. A plurality of inorganic solar cells is provided outside of the cavity. At least one thermocouple is formed such that the cavity corresponds to a hot side of the at least one thermocouple and an area outside the cavity proximate to the plurality of solar cells corresponds to a cold side of the at least one thermocouple.

The features, aspects, advantages, and example embodiments described herein may be combined to realize yet further embodiments.

### BRIEF DESCRIPTION OF THE DRAWINGS

These and other features and advantages may be better and more completely understood by reference to the following detailed description of exemplary illustrative embodiments in conjunction with the drawings, of which:

FIG. 1 is a schematic cross-sectional view of thermoelectric modules embedded in a vacuum insulating glass (VIG) unit in accordance with an example embodiment;

FIG. 2 is a schematic top or plan view of thermoelectric modules that are electrically connected in serial, thermally connected in parallel, and embedded in a vacuum insulating glass (VIG) unit in accordance with an example embodiment;

FIG. 3 is a schematic cross-sectional view of a hybrid system including thermoelectric modules and strip solar cells provided in connection with a vacuum insulating glass (VIG) unit in accordance with an example embodiment;

FIG. 4 plots thermoelectric efficiency as a function of the Z-value and the temperature differential between the hot and cold junction;

FIG. 5 is a flowchart showing an illustrative process for making a hybrid system including thermoelectric modules and strip solar cells provided in connection with a vacuum insulating glass (VIG) unit in accordance with an example embodiment;

FIG. 6 illustrates the operational principle of a waveguide in accordance with an example embodiment;

FIGS. 7A-7C are schematic views of imaging, non-imaging, and micro-optic slab lenses in accordance with an example embodiment; and

FIG. 8 is a schematic cross-sectional demonstrating how a pillar waveguide may work in accordance with an example embodiment.

### DETAILED DESCRIPTION OF EXAMPLE EMBODIMENTS OF THE INVENTION

Certain example embodiments provide techniques for improving the output of hybrid systems comprising photovoltaic (PV) and thermoelectric (TE) modules in conjunction with super-insulating, yet optically transmissive, vacuum insulated glass (VIG) unit technologies. More particularly, certain example embodiments relate to hybrid systems including hydrogenated microcrystalline silicon (mc-Si), hydrogenated amorphous silicon (a-Si), bulk hetero-junction solar cell, and/or the like, that may be used together with a TE generator, that achieves high operational PV and TE efficiencies under ambient conditions. In that regard, certain example embodiments effectively partition the solar spectrum in order to yield an increased conversion efficiency of a PV-TE hybrid system with a solar cell operating at ambient temperature.

In certain example embodiments, a vacuum insulated glazing (VIG) unit is used as a medium of high thermal resistance (R>12) to house thermoelectric junctions arrays, which are electrically in series and thermally in parallel, on the side facing the sun. According to certain example embodiments, the R-value preferably is at least 10, more preferably at least 12, and possibly even higher. High R-values such as these are currently achievable in VIG units manufactured by the assignee of the instant invention. Such units generally incorporate fired pillars and low-E coatings. Of course, a typical argon- and/or xenon-filled IG unit provides an R-value of about 4, and may be used in connection with certain example embodiments provided that the TE coefficient of merit Z is increased to a suitable level, e.g., as discussed in greater detail below. In any event, an R-value of 10 will provide a delta T of about 400 degrees C., and an R-value of about 12 will provide a delta T of about 600 degrees C.

The number of junctions per unit area preferably is provided at a level such that the fill factor is less than 20%. As is known, fill factor refers to the ratio (given as percent) of the actual maximum obtainable power to the theoretical power. This fill factor allows substantial visible light to be transmitted and focused or concentrated onto a solar cell positioned on the cold side of the VIG unit. Of course, it will be appreciated that the fill factor may be balanced with the Z-value, similar to as noted above. Thus, where the Z-value is greater than or equal to about 10, the fill factor may be reduced to less than or equal to about 10%.

According to certain example embodiments, the VIG unit may serve multiple purposes. For example, the VIG unit may provide a support for the TE junctions, which may be integrated within the VIG. As another example, the VIG unit may provide for very large temperature differentials between the hot and cold junctions via the inclusion of the TE devices within the VIG unit itself. The large delta T, in turn, may help increase the TE efficiency substantially. As still another example, the VIG unit may provide support for a cylindrical lens array to focus visible light onto an array of solar cells. As still another example, the VIG unit may help thermally insulate the solar cell and prevent the PV junction from reaching temperatures that will degrade its operational efficiency.

Advantageously, certain example embodiments allow for the use of inorganic semiconductor-based PV installations that use smaller amounts of active material and that are kept cool while still receiving an increased amount of concentrated light. Also advantageously, certain example embodiments provide highly efficient thermo-generation because of the high-temperature differential related to TE modules being provided in the VIG unit with the high R-value. In that regard, certain example embodiments may include, e.g., insulation to help keep the panel hot. Insulation may be provided on or around the perimeter of the VIG unit. Any suitable material may be used to accomplish this insulation function including, for example, plastics such as the materials currently used in insulating glass (IG) spacers.

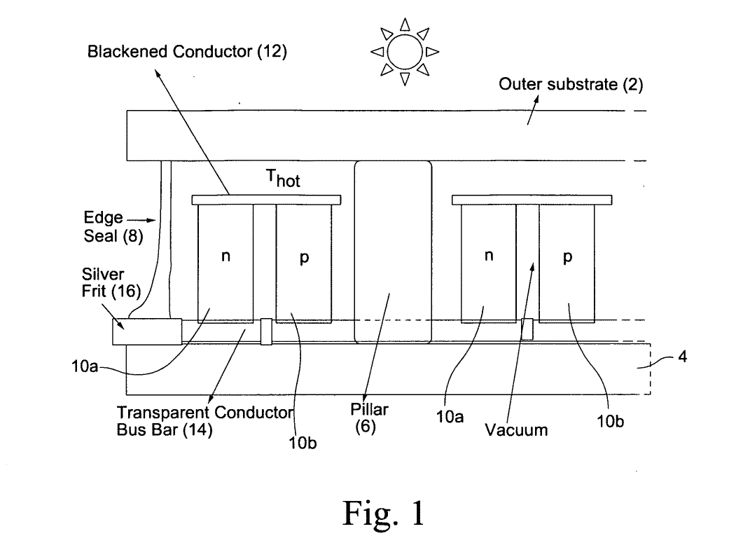

FIG. 1 is a schematic cross-sectional view of thermoelectric modules embedded in a vacuum insulating glass (VIG) unit in accordance with an example embodiment. Similar to conventional VIG units, the FIG. 1 example embodiment includes an outer substrate 2 and an inner substrate 4. One or both of the outer and inner substrates 2 and 4 may be glass substrates in certain example embodiments of this invention. The substrates are provided substantially parallel, spaced apart relation to one another, and a plurality of pillars 6 help maintain the distance between the outer and inner substrates 2 and 4. The pillars 6 may be sapphire pillars in certain example embodiments of this invention. An edge seal 8 is provided around the periphery to hermetically seal the VIG unit, e.g., so that a the cavity between the outer and inner substrates 2 and 4 may be evacuated to a pressure less than atmospheric and/or filled with a gas or gasses (such as, for example, argon, xenon, and/or the like). The outer and inner substrates 2 and 4 may be the same or different sizes in different embodiments of this invention.

As explained above, thermoelectric modules are provided such that the hot side of the thermocouple is located in the cavity of the VIG unit whereas the cold side of the thermocouple is located exterior to the inner substrate 4 (e.g., proximate surface 4). The hot side of each thermoelectric module includes an n-leg 10a and a p-leg 10b and may be made of any suitable material. For example, the thermoelectric module may be bismuth-based (e.g., Bi₂Te₃, Bi₂Se₃, etc.), skutterudite materials (e.g., in the form of (Co,Ni,Fe)(P,Sb,As)₃ or the like), oxides (e.g., (SrTiO₃)ₙ(SrO)ₘ or the like), etc. The thermoelectric material may be doped in certain example embodiments. When the TE material is doped, for example, the doping may be graded such that the doping is higher proximate to the hot junction.

The n-leg 10a and a p-leg 10b of the modules may be connected by a conductor 12, sometimes referred to as a blackened conductor because of the material used therein, even though light may still be transmitted therethrough. The conductor 12 may in certain example embodiments be a copper-based material (Cu, CuO, etc.), a frit (e.g., of carbon black such as DAG or the like), a CNT-based ink, etc. The thermoelectric modules may be screen printed in certain example embodiments of this invention. The size of each module may be selected in conjunction with the desired fill factor. When a 20% fill factor is used, for example, a substantially square approximately 1″×1″ module size may be used, although other sizes and/or shapes are possible in connection with this and/or other fill factors. In certain example embodiments, the pillars 6 may be placed following the screen printing of the TE materials.

In certain example embodiments, the TE modules are not in direct contact with the inner substrate 4. Instead, in certain example embodiments, a bus bar 14 is provided between the inner surface of the inner substrate 4 (surface 3) and the thermoelectric materials. This bus bar may be transparent and thus may be of or include any suitable material such as, for example, a transparent conductive coating of or including Ag, ITO, AZO, indium-galluim-oxide, etc. The conductive coating may also be a CNT-based, graphene based, etc. CNT-based conductive coatings/devices and methods of making the same are disclosed in, for example, U.S. application Ser. No. 12/659,352, the disclosure of which is hereby incorporated herein by reference, and graphene-based conductive coatings/devices and methods of making the same are disclosed in, for example, U.S. application Ser. No. 12/654,269, the disclosure of which is hereby incorporated herein by reference. To help facilitate the transfer of power, a silver or other conductive frit 16 may be provided proximate to the edge of the VIG unit and in direct or indirect contact with the bus bar 14. In certain example embodiments, the edge seal 8 itself may be formed from a conductive material and thus may serve as the appropriate connection.

Although not shown in FIG. 1, a light scattering thin film layer may be provided on one or both of the inner and outer surfaces of the outer substrate 2 (surface 1 or 2), e.g., so as to help increase performance of the TE modules. Similarly, although not shown in FIG. 1, a low-E coating may be provided on one or both of the inner and outer surfaces of the inner substrate 4 (surface 3 or 4). This low-E coating may be antireflective with respect to visible light (or portions thereof) and/or IR reflecting (or portions thereof). In certain example embodiments, the resistivity and optical properties of the bus bar 14 may be tuned so as to be sufficiently conductive to serve as the bus bar while also being antireflective with respect to visible light (or portions thereof) and/or IR reflecting (or portions thereof).

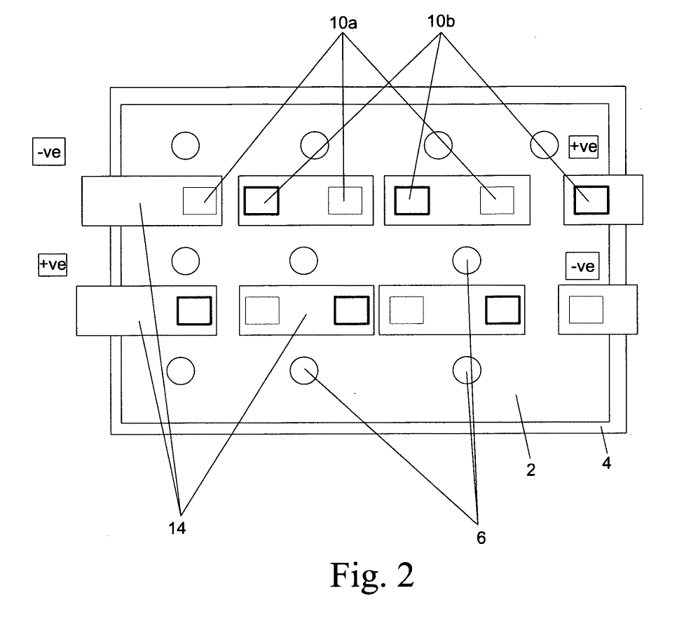

FIG. 2 is a schematic top or plan view of thermoelectric modules that are electrically connected in serial, thermally connected in parallel, and embedded in a vacuum insulating glass (VIG) unit in accordance with an example embodiment. The TE modules are electrically connected in serial such that the n-leg in a first module is connected to the p-leg in a second module (or vice versa), etc., until the end of a row or column, and then adjacent columns or rows are connected, and the pattern repeats along the new row. The TE modules are thermally connected in parallel because they are all located within the cavity of the VIG unit. Each side of the VIG unit contains at least one positive terminal and at least one negative terminal. The silver frit discussed above thus may provide around substantially the entire periphery of the VIG unit, at locations where the terminals are to be provided, etc. As can be seen from FIG. 2, the TE modules occupy space such that a predetermined fill factor is met (in this example case, about 20%).

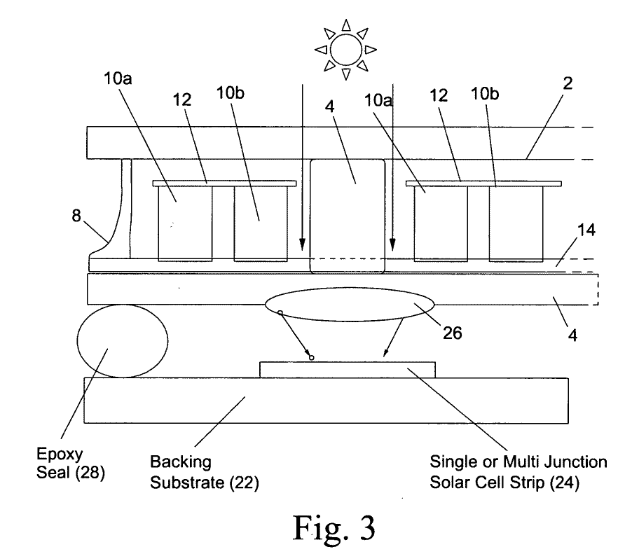

FIG. 3 is a schematic cross-sectional view of a hybrid system including thermoelectric modules and strip solar cells provided in connection with a vacuum insulating glass (VIG) unit in accordance with an example embodiment. The FIG. 3 example embodiment is similar to the portion shown in FIG. 1 in that a VIG unit includes outer and inner substrates 2 and 4 that are maintained in substantially parallel spaced-apart relation to one another by virtue of pillars 6 and an edge seal 8, and in that the at least partially evacuated cavity includes a plurality of TE modules comprising n-legs 10a and p-legs 10b connected by conductors 12 such that the TE modules are electrically in series and thermally in parallel.

In accordance with certain example embodiments, the cool side of the thermocouples serves as a platform or otherwise supports a plurality of solar cells. Thus, as shown in FIG. 3, a backing substrate 22 is provided. The backing substrate 22 may be a glass substrate, polymer, plastic, or other suitable substrate in different embodiments of this invention, and it supports single or multi junction solar cell strips 24. Light from the sun may be focused or concentrated on the solar cell strips 24 by virtue of lenses 26 connected to or integrally formed with the inner substrate 4. In certain example embodiments, the lenses 26 and/or solar cell strips 24 may be located substantially in-line with the columns 6.

Lens arrays and strip solar cells, including example techniques for making the same, are disclosed in, for example, U.S. application Ser. Nos. 12/662,628 and 12/662,624, the disclosures of which are hereby incorporated herein by reference.

The lenses 26 may be substantially columnar in shape according to certain example embodiments of this invention, and the lenses 26 may be formed in any suitable way. For instance, float glass used for the inner substrate 4 may be patterned and/or etched in certain example instances. In certain other example instances, a pre-formed lens may be laminated to the inner substrate 4 using any suitable laminate material (such as, for example, PVB, EVA, optibond, etc.). In still other example instances, glass may be melted to form a lens puddle that may be actively cooled or allowed to cool. This technique may be advantageous in terms of glass strength, e.g., as compared to glass having an alternating thick/thin pattern. In any event, the material used for the lens may be doped with higher refractive index material.

An epoxy or other seal 28 may be used to help maintain the backing substrate 2 in substantially parallel spaced apart relation to the inner substrate 4 (and thus the outer substrate 2, as well). A plurality of pillars (not shown) also may be provided to help maintain this arrangement. Thus, the FIG. 3 example embodiment may be thought of as being a combined VIG and IG combined assembly, with the VIG portion of the assembly housing the TE modules and the IG portion of the assembly housing the PV-related components. In still other example embodiments, it may be possible to provide a so-called triple VIG, in that the cavity between the inner substrate 4 and the backing substrate 22 may be at least partially evacuated and/or filled with an appropriate (e.g., inert) gas.

In certain example embodiments, however, the seal 28 and/or pillars may not be necessary, as solar cells themselves may serve as pillars separating the inner substrate 4 and the backing substrate 22. In certain example embodiments, the solar cells may be supported by the inner substrate 4 rather than a backing substrate 22. In such cases, it is possible to simply encapsulate or otherwise provide a laminate over the solar cells, e.g., so as to protect them from the environment, thereby reducing the need for a separate backing substrate 22.

In certain example embodiments, the pillars 26 may serve as waveguides. In such cases, it is possible to dope the pillars with a chromophore or other chemical group capable of selective light absorption. As is known, visible light that hits the chromophore may be absorbed by exciting an electron from its ground state into an excited state. The pillars therefore may include a chromophore that absorbs certain wavelengths of visible light and transmits those wavelengths of visible light that are particularly well matched to the solar cell material (e.g., Si wafer). The ability to provide a waveguide may therefore help to improve the efficiency of the solar cells yet further and may reduce (or completely eliminate) the need for concentrating lenses in certain example embodiments. Further details pertaining to the waveguiding of incident light to achieve high solar flux are provided below.

As indicated above, PV systems that incorporate inorganic solar cells typically drop in efficiency as heat increases. Providing the PV systems on the cool side of the thermocouple or “behind” the VIG thus may result in efficiency gains. To further improve efficiency, power generated by the TE modules may be used to help cool the solar cells.

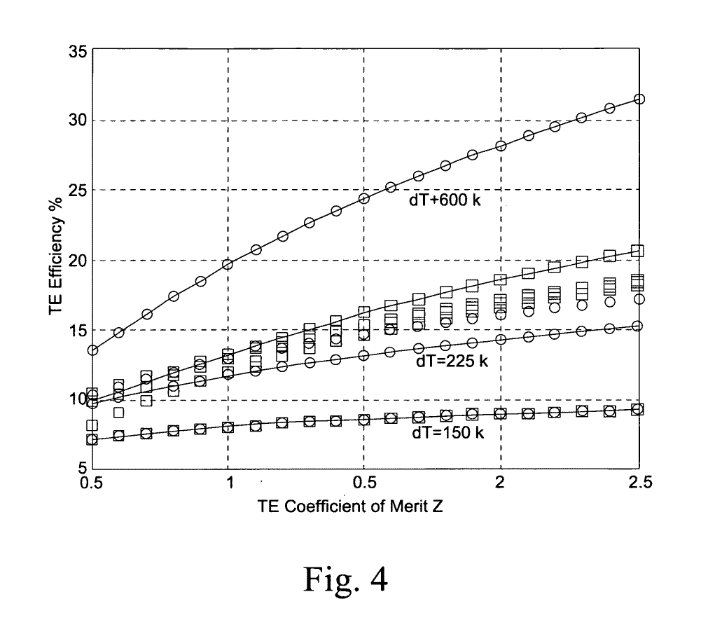

FIG. 4 plots thermoelectric efficiency as a function of the Z-value and the temperature differential between the hot and cold junction. As can be seen from the FIG. 4 graph, the thermoelectric efficiency increases with the coefficient of merit Z, as well as with the temperature differential between the hot and cold sides. As can be seen, efficiency increases very rapidly where delta T is 600 degrees, even for modest Z-values.

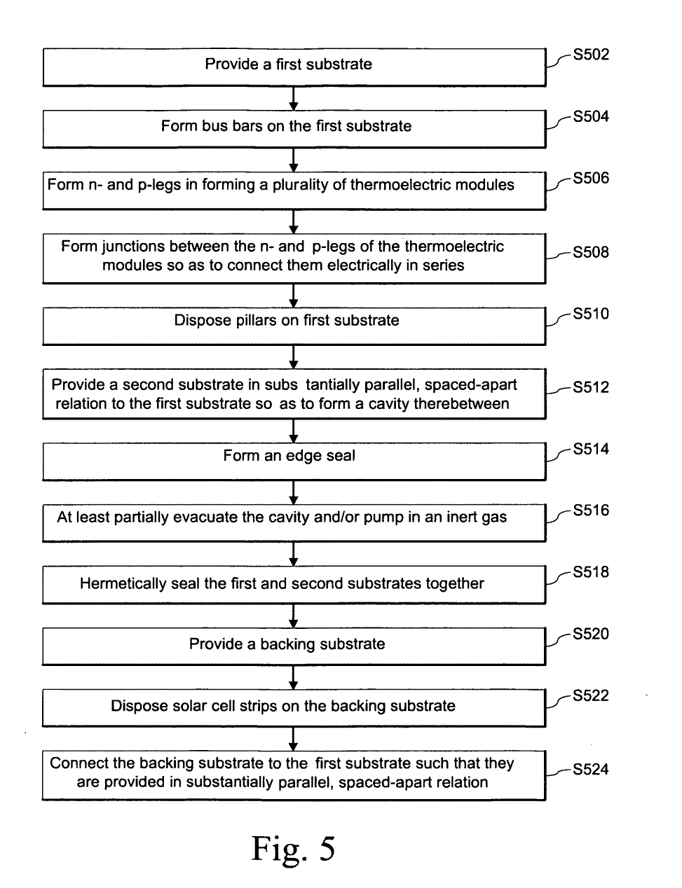

FIG. 5 is a flowchart showing an illustrative process for making a hybrid system including thermoelectric modules and strip solar cells provided in connection with a vacuum insulating glass (VIG) unit in accordance with an example embodiment. The FIG. 5 example process essentially corresponds to manufacturing the TE components first in connection with the manufacturing of a VIG unit, followed by the manufacturing of the PV-related components. Of course, it will be appreciated that these steps may be performed in different orders in different embodiments of this invention. It also will be appreciated that the further steps in these sub-processes may be performed in different orders, as well.

Vacuum insulating glass (VIG) units are known in the art. For example, see U.S. Pat. Nos. 5,664,395; 5,657,607; and 5,902,652, U.S. Publication Nos. 2009/0151854; 2009/0151855; 2009/0151853; 2009/0155499; 2009/0155500, and U.S. application Ser. Nos. 12/453,220; 12/453,221, the disclosures of which are all hereby incorporated herein by reference. The edge seal, pump-out, and/or other techniques/configurations of these references may be used in connection with certain embodiments of this invention.

A first substrate is provided in step S502. The first substrate corresponds to the inner substrate of the VIG unit. Bus bars are formed in step S504. This may be accomplished by disposing (e.g., through sputtering, wet application, or other coating techniques) a conductive material on the first substrate and etching, as appropriate. In step S506, n- and p-legs are formed for a plurality of thermoelectric modules. Junctions are formed between the n- and p-legs of the thermoelectric modules so as to connect them electrically in series in step S508. The TE modules may be formed, for example, by screen printing or any other suitable deposition technique, e.g., so that they are provided in appropriate locations and to appropriate sizes in order to match a desired fill factor with respect to the PV modules.

A plurality of pillars may be disposed on the first substrate in step S510, and these pillars optionally may serve as waveguides as discussed above. A second second substrate (which will serve as the outer substrate of the VIG unit) is provided in step S512 such that it is in substantially parallel, spaced-apart relation to the first substrate and such that the first and second substrates form a cavity therebetween. An edge seal is formed in step S514. The edge seal optionally may include or abut a conductive frit at portions thereof for external electrical connections or may be conductive itself The cavity is at least partially evacuated and/or an inert gas (e.g., Ar, Xe, or the like) is pumped therein in step S516. In step S518, the first and second substrates may be hermetically sealed together, e.g., in forming the VIG unit. It will be appreciated that the VIG unit may have R-values in the range specified above.

A backing substrate is provided in step S520. Solar cell (e.g., in strip form and optionally of or including an inorganic material such as me-Si, c-Si, a-Si, or the like) are disposed on the backing substrate in step S522. Optionally, lenses may be oriented on the first substrate so that they focus incident light on the solar cells, e.g., if such lenses are desired and if they are not already integrally formed with the first substrate. In step S524, the backing substrate is connected to the first substrate such that they are provided in substantially parallel, spaced-apart relation to one another. This may be accomplished using, for example, an edge seal and pillars similar to a conventional IG unit. In certain example embodiments, the solar cells themselves may serve as the pillars. In place of, or in addition to steps S520-S524, the solar cells may be supported by the first substrate and protected with another substrate, laminate material, or the like.

As indicated above, it is possible to use the pillars of the VIG unit as waveguides. In so doing, it may be possible to achieve a very high solar flux, e.g., around 500× concentration. Such example implementations are advantageous, as III-V multi junction PV cells provide efficiencies surpassing 40% when illuminated with high solar flux (up to 500×). It will be appreciated that combining small-area, high-efficiency PV cells with inexpensive concentrator optics can potentially reduce costs while also reducing the system footprint.

CPV optics collect insolation while high flux systems actively track the sun's daily position. Large aperture concentrators are typically difficult to mount for tracking because of their considerable physical weight and volume, and due to wind-loading forces on the extended surface. Nevertheless, most CPV systems rely on bulky optics such as parabolic dishes or imaging lenses. These elements produce demagnified images of the sun and can yield high levels of concentration (>1000×), but produce non-uniform flux distributions and require very accurate alignment.

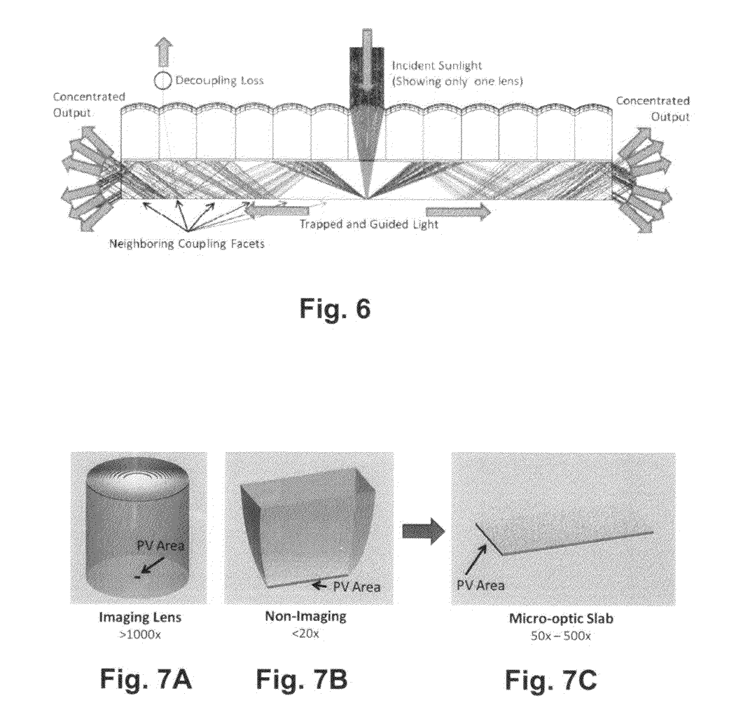

By contrast, certain example embodiments combine the waveguide structure with an efficient light injection technique. The micro-optic slab concentrator may in certain example implementations combine an array of lenses with a multimode slab waveguide (e.g., low-iron glass). Each lens element may form a focus within the guide and be redirected into guided modes propagating laterally within the glass slab. Light thus exits from the slab edge or waveguide slot onto a PV cell. Efficient coupling into the waveguide is possible using small area reflective microstructures located at each lens focus, where the image of the sun is formed. The example configuration has additional benefits of producing a uniform intensity distribution at the PV cell as well as passing diffuse illumination for possible collection using flat-panel cells. Initial alignment between the lens focus and coupling mechanism helps capture incident sunlight. This example behavior is shown visually in FIG. 6. Certain example embodiments implement self-alignment, enabling the coupling structure to be molded in a photoresist and polymerized at each focus using the lens array as a mask. This may help assure accurate alignment between the lens array and coupling features. The process also may potentially yield very large, inexpensive concentrators when performed using roll-to-roll manufacture.

The micro-optic slab concentrator of certain example embodiments acts as a hybrid imaging/non-imaging optical system by combining an imaging lens array formed by the pillars and with the bottom glass acting as a multi-mode slab waveguide. FIGS. 7A-7C are schematic views of imaging, non-imaging, and micro-optic slab lenses in accordance with an example embodiment. The optical system may be thought of as including three main components. The first component is a two-dimensional lens array acting as an upward facing aperture to collect incident solar radiation. Each lens forms a de-magnified image of the solar disk which subtends, e.g., ±0.26° (4.7 mrad). (ii) A high refractive index slab waveguide, the second element, sits beneath the lens array. Localized structures embedded on the backside of the waveguide reorient focused light into guided modes that travel via total internal reflection (TIR) transversely within the slab. The top surface of the waveguide may be separated from the lenses by a thin layer of low-index cladding. Large index contrasts between the core and cladding may promote greater numbers of guided modes and allow steep marginal rays to TIR at the interface. The non-imaging nature of the slab waveguide allows light to be collected from several lens apertures at large ray angles.

The third component of the concentrator is the mechanism that efficiently couples light into the waveguide. Gratings and holograms have previously been used for waveguide coupling; however, the broad spectrum of sunlight presents difficulties for these solutions in terms of efficiency. Certain example embodiments may instead use specular reflections from small fold mirrors that can reorient the sunlight into angles that exceed the critical angle between the guiding slab and cladding interface and therefore guide by TIR. For instance, a 120° prism design may substantially symmetrically couple radiation into the slab, guiding light towards two opposing edges. In order to collect the concentrated light, the PV cells may simply be placed at each output edge. A reflective coating may be applied to one of the edges to direct all radiation towards one side of the guiding slab, if so desired. This single-sided configuration may be very efficient despite the increased path length because of low losses within the low Fe glass slab waveguide. Additionally, using one PV cell doubles the geometric concentration ratio, allowing systems to become physically shorter while still being efficiency.

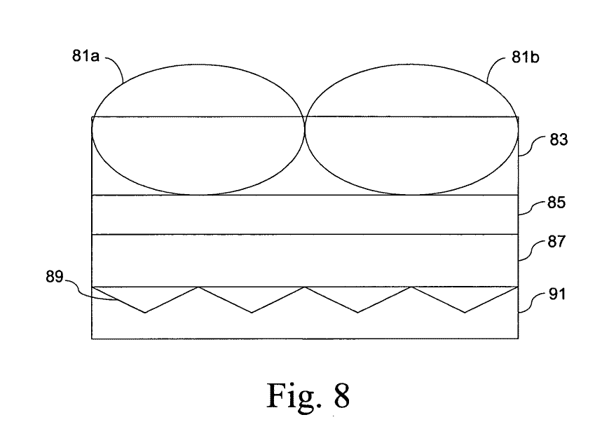

FIG. 8 is a schematic cross-sectional view of the three components of a waveguide discussed above in accordance with an example embodiment. Light comes into contact with the lenses 81a and 81b and is focused through an optional supporting substrate 83 that may be laminated to a planar waveguide 87 (which may be a glass substrate), e.g., using a low-index laminate or cladding 85 (of or comprising any suitable material such as EVA). The lenses may be glass, polymer, or any suitable material in different embodiments of this invention. The light in this waveguided mode reaches the mirrored coating 89, which optionally may be supported by a mirror coupler 91.

As will be appreciated from the above, certain example embodiments collect light over substantially the entire length of the spectrum in a manner that is very efficient—even without tracking. Indeed, calculations of some samples show at least a 500× light concentration capability.

Although certain example embodiments have been described in connection with inorganic solar cell materials, different example embodiments may use organic solar cells. In such cases, the exposure to heat may not be as large an issue and the exposure to IR radiation actually may be beneficial. In such cases, it is possible to provide a similar structure to that described herein, except that the PV portion of the system may be provided closer to the sun than the TE portion, and/or the PV portion and the TE portion both may be housed within the VIG unit. As one example, the FIG. 3 embodiment may essentially be “flipped” such that the backing substrate 22 becomes the substrate closest to the sun. As another example, both the TE modules and the solar cells may be provided within the VIG unit shown in FIG. 1, with either the PV portion being provided on surface 1 (the inner surface of the outer substrate) and the TE modules being provided on surface 2 (the inner surface of the inner substrate), or vice versa.

Certain example embodiments may incorporate as one or more of the substrates a low-iron glass. Example low-iron glass substrates are disclosed, for example, in U.S. Publication Nos. 2006/0169316; 2006/0249199; 2007/0215205; 2009/0223252; and 2009/0217978, as well as U.S. application Ser. Nos. 12/292,346; 12/385,318; and 12/453,275, the entire contents of each of which are hereby incorporated herein by reference.

It will be appreciated that the techniques described herein may be used in connection with a variety of applications. For instance, modules may be disposed on rooftops or in open fields in different example embodiments. Such systems may be provided in connection with single-axis or dual-axis tracking systems as disclosed in, for example, U.S. application Ser. Nos. 12/662,628 and 12/662,624, as referenced above. Window or window-like applications such as skylights, spandrels, etc., also are possible where the total visible transmission is relatively high (e.g., at least about 50%, more preferably at least about 60%).

“Peripheral” and “edge” seals herein do not mean that the seals are located at the absolute periphery or edge of the unit, but instead mean that the seal is at least partially located at or near (e.g., within about two inches of) an edge of at least one substrate of the unit. Likewise, “edge” as used herein is not limited to the absolute edge of a glass substrate but also may include an area at or near (e.g., within about two inches of) an absolute edge of the substrate(s).

As used herein, the terms “on,” “supported by,” and the like should not be interpreted to mean that two elements are directly adjacent to one another unless explicitly stated. In other words, a first layer may be said to be “on” or “supported by” a second layer, even if there are one or more layers therebetween.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

What is claimed is:

1. An assembly, comprising:
first and second substantially parallel, spaced-apart substrates at least partially defining a cavity therebetween, the cavity being evacuated to a pressure less than atmospheric;
a plurality of pillars provided between the first and second substrates;
an edge seal provided around the periphery of the first and/or second substrate(s);
at least one bus bar provided in the cavity and supported by the second substrate;
a plurality of thermoelectric modules located in the cavity and on the at least one bus bar such that said thermoelectric modules are thermally in parallel, each said thermoelectric module including a n-leg and a p-leg; and
a third substrate supporting at least one solar cell, the third substrate being substantially parallel to the second substrate and being located on a side of the second substrate opposite the first substrate,
wherein at least one thermocouple is formed such that the cavity corresponds to a hot side of the at least one thermocouple and an area outside the cavity proximate to the third substrate corresponds to a cold side of the at least one thermocouple, and
wherein adjacent thermoelectric modules are connected to one another via junctions such that the thermoelectric modules are electrically in series.

2. The assembly of claim 1, further comprising a plurality of solar cells, each said solar cell being a solar cell strip.

3. The assembly of claim 2, further comprising a plurality of lenses located on or integrally formed with the second substrate, the plurality of lenses being arranged to concentrate light in the visible spectrum on at least one respective solar cell strip.

4. The assembly of claim 3, further comprising a seal arranged between the second and third substrates to help maintain the second and third substrates in substantially parallel, spaced-apart relation to one another.

5. The assembly of claim 2, wherein each said pillar includes chromophore such that each said pillar is arranged to function as a waveguide filtering visible light in a spectrum matched to the solar cell material.

6. The assembly of claim 2, wherein the first and second substrates form a vacuum insulating glass (VIG) unit having an R-value of at least about 10.

7. The assembly of claim 2, wherein the first and second substrates form a vacuum insulating glass (VIG) unit having an R-value of at least about 12.

8. The assembly of claim 2, wherein the number of junctions per unit area corresponds to a fill factor of less than about 20%.

9. The assembly of claim 1, further comprising a conductive frit included in or abutting the edge seal.

10. The assembly of claim 1, wherein n-legs and p-legs are doped such that the dopant is graded to be higher proximate to the junctions.

11. A method of making a hybrid thermoelectric/photovoltaic system, the method comprising:
providing a first substrate;
forming at least one bus bar on the first substrate;
forming a plurality of thermoelectric modules on the first substrate at least partially over the at least one bus bar, each said thermoelectric module including an n-leg and a p-leg;
forming junctions between adjacent thermoelectric modules so as to electrically connect the thermoelectric modules in series;
providing a plurality of pillars on the first substrate;
providing a second substrate in substantially parallel, spaced-apart relation to the first substrate so as to at least partially define a cavity therebetween;
forming an edge seal around the periphery of the first and/or second substrate(s);
evacuating the cavity to a pressure less than atmospheric;
providing a backing substrate;
disposing at least one solar cell on the backing substrate; and
connecting the backing substrate to the first substrate such that the second substrate and the backing substrate are provided in substantially parallel, spaced-apart relation to one another, the side of the backing substrate having the at least one solar cell disposed thereon facing a side of the first substrate that does not have the plurality of thermoelectric modules formed thereon,
wherein at least one thermocouple is formed such that the cavity corresponds to a hot side of the at least one thermocouple and an area outside the cavity proximate to the backing substrate corresponds to a cold side of the at least one thermocouple, and
wherein the plurality of thermoelectric modules is thermally in parallel in the cavity.

12. The method of claim 11, further comprising providing a plurality of solar cells, each said solar cell being a solar cell strip.

13. The method of claim 12, further comprising providing a plurality of lenses located on or integrally formed with the second substrate, the plurality of lenses being arranged to concentrate light in the visible spectrum on at least one respective solar cell strip.

14. The method of claim 12, wherein each said pillar includes chromophore such that each said pillar is arranged to function as a waveguide filtering visible light in a spectrum matched to the solar cell material.

15. The method of claim 12, wherein the first and second substrates form a vacuum insulating glass (VIG) unit having an R-value of at least about 10.

16. The method of claim 12, wherein the number of junctions per unit area corresponds to a fill factor of less than about 20%.

17. The method of claim 11, further comprising providing a conductive frit in or on the edge seal.

18. The method of claim 11, wherein a temperature differential between the hot and cold sides of the at least one thermocouple of at least about 400 degrees C. is reachable.

19. The method of claim 11, wherein n-legs and p-legs are doped such that the dopant is graded to be higher proximate to the junctions

20. A hybrid thermoelectric/photovoltaic system, comprising:
a vacuum insulating glass (VIG) unit including a cavity evacuated to a pressure less than atmospheric;
at least one bus bar provided in the cavity;
a plurality of thermoelectric modules located in the cavity and on the at least one bus bar such that said thermoelectric modules are thermally in parallel, the thermoelectric modules including junctions between adjacent n- and p-legs of the thermoelectric modules such that the thermoelectric modules are electrically in series; and
a plurality of inorganic solar cells provided outside of the cavity,
wherein at least one thermocouple is formed such that the cavity corresponds to a hot side of the at least one thermocouple and an area outside the cavity proximate to the plurality of solar cells corresponds to a cold side of the at least one thermocouple.
